(19) United States
(12) Patent Application Publication
(10) Pub. No.: US 2026/0317897 A1
(43) Pub. Date: Oct. 15, 2026

(54) SUBSTRATE PROCESSING METHOD AND PLASMA PROCESSING APPARATUS

(71) Applicant: Tokyo Electron Limited, Tokyo (JP)

(72) Inventors: Daisuke OBA, Albany, NY (US); Nobuo MATSUKI, Yamanashi (JP); Yoshinori MORISADA, Yamanashi (JP)

(21) Appl. No.: 19/695,528

(22) Filed: Jun. 2, 2026

Related U.S. Application Data
(63) Continuation of application No. PCT/JP2024/041938, filed on Nov. 27, 2024.

(30) Foreign Application Priority Data
Dec. 12, 2023 (JP) 2023-209601

(51) Int. Cl. C23C 16/30; C23C 16/56; H01J 37/32

(52) U.S. Cl. CPC C23C 16/30; C23C 16/56; H01J 37/32449; H01J 2237/332

(57) ABSTRACT

A substrate processing method includes: (A) preparing a substrate; (B) forming, on a surface of the substrate, a metal-containing film that contains oxygen, a first ligand, and a second ligand, the first ligand and the second ligand having different thermal reactivities; (C) heat-treating the metal-containing film; and (D) irradiating the metal-containing film with extreme ultraviolet rays under a predetermined pattern, to form an exposed part irradiated with the extreme ultraviolet rays and an unexposed part not irradiated with the extreme ultraviolet rays in the metal-containing film.

### CROSS-REFERENCE TO RELATED APPLICATIONS

This application is a continuation application of International Application No. PCT/JP2024/041938, filed on Nov. 27, 2024, and designating the U.S., which is based upon and claims priority to Japanese Patent Application No. 2023-209601, filed on Dec. 12, 2023, the entire contents of which are incorporated herein by reference.

### BACKGROUND

### Technical Field

The present disclosure relates to a substrate processing method and a plasma processing apparatus.

### Background Art

Japanese Translation of PCT International Patent Application Publication No. 2022-538555 discloses a method including: depositing a metal oxide-based Extreme Ultra Violet (EUV) photoresist on a substrate; next, after subjecting the substrate to a heat treatment referred to as Post-Apply Bake (PAB), exposing the substrate to EUV rays in order to pattern the resist, to thereby form exposed regions and unexposed regions; and, next, after subjecting the substrate to a heat treatment referred to as Post-Exposure Bake (PEB), selectively removing the unexposed regions.

Japanese Patent Application Laid-Open Publication No. 2015-201622 discloses a photoresist-less method of forming a metal hard mask, including: depositing an EUV-sensitive metal-containing film on a semiconductor substrate; and, next, exposing the metal-containing film directly to EUV in a vacuum environment, to thereby pattern the metal-containing film and form a metal hard mask.

Japanese Patent Application Laid-Open Publication No. 2017-116923 discloses a method of forming a metal oxide-containing hard mask, including: depositing an EUV-sensitive metal-oxide-containing film on a semiconductor substrate by evaporative deposition; next, exposing a part of the metal oxide-containing film to EUV to form a pattern in the metal oxide-containing film; and, next, developing the pattern in the metal oxide-containing film in order to form a metal oxide-containing hard mask, to thereby remove either the exposed part or the unexposed part.

### SUMMARY

According to one aspect of the present disclosure, a substrate processing method is provided, including: (A) preparing a substrate; (B) forming, on a surface of the substrate, a metal-containing film that contains oxygen, a first ligand, and a second ligand, the first ligand and the second ligand having different thermal reactivities; (C) heat-treating the metal-containing film; and (D) irradiating the metal-containing film with extreme ultraviolet rays under a predetermined pattern, to form an exposed part irradiated with the extreme ultraviolet rays and an unexposed part not irradiated with the extreme ultraviolet rays in the metal-containing film.

### BRIEF DESCRIPTION OF THE DRAWINGS

FIG. 1 is a schematic cross-sectional view showing an example of a plasma processing apparatus;

FIG. 2 shows an example of film structures in steps for forming a metal-containing resist film according to a reference example;

FIG. 3 is a flowchart showing an example of a method for forming a metal-containing resist film according to a first embodiment;

FIG. 4A is a diagram showing an example of a film cross-section in each step for forming a film according to the first embodiment;

FIG. 4B is a diagram showing an example of a film cross-section in each step for forming a film according to the first embodiment;

FIG. 4C is a diagram showing an example of a film cross-section in each step for forming a film according to the first embodiment;

FIG. 4D is a diagram showing an example of a film cross-section in each step for forming a film according to the first embodiment;

FIG. 4E is a diagram showing an example of a film cross-section in each step for forming a film according to the first embodiment;

FIG. 4F is a diagram showing an example of a film cross-section in each step for forming a film according to the first embodiment;

FIG. 5 shows an example of film structures in each step for forming a film according to the first embodiment;

FIG. 6 is a graph showing an example of a result of an experiment regarding dependency of the solubility of a metal-containing film on temperature;

FIG. 7 is a graph showing an example of a result of an experiment regarding sensitivity of a metal-containing film;

FIG. 8 is a flowchart showing an example of a method for forming a metal-containing resist film according to a second embodiment;

FIG. 9A is a diagram showing an example of a film cross-section in each step for forming a film according to the second embodiment;

FIG. 9B is a diagram showing an example of a film cross-section in each step of forming a film according to a second embodiment;

FIG. 9C is a diagram showing an example of a film cross-section in each step for forming a film according to the second embodiment;

FIG. 9D is a diagram showing an example of a film cross-section in each step for forming a film according to the second embodiment;

FIG. 9E is a diagram showing an example of a film cross-section in each step for forming a film according to the second embodiment; and

FIG. 10 shows an example of film structures in each step for forming a film according to the second embodiment.

### DETAILED DESCRIPTION OF THE INVENTION

Hereinafter, an embodiment of the present disclosure will be described with reference to the drawings. In the drawings, the same components are denoted by the same reference numerals, and redundant descriptions thereof may be omitted.

### Plasma Processing Apparatus

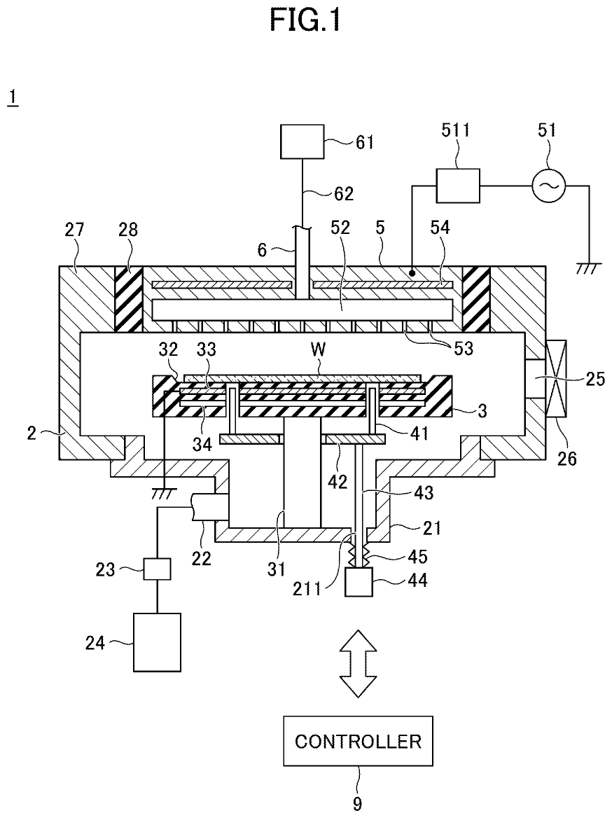

An example of a plasma processing apparatus 1 will be described with reference to FIG. 1. FIG. 1 is a schematic cross-sectional view showing an example of the plasma processing apparatus 1. The plasma processing apparatus 1 is an example of an apparatus for forming a metal-containing film on a substrate W, such as a semiconductor wafer and the like, by a Chemical Vapor Deposition (CVD) method using plasma.

The plasma processing apparatus 1 includes a substantially cylindrical airtight processing vessel 2. A gas exhaust chamber 21 is provided in the center of the bottom wall of the processing vessel 2.

The gas exhaust chamber 21 has, for example, a substantially cylindrical shape projecting downward. A gas exhaust flow path 22 is connected to the gas exhaust chamber 21, for example, on a side surface of the gas exhaust chamber 21.

A gas exhaust 24 is connected to the gas exhaust flow path 22 via a pressure adjuster 23. The pressure adjuster 23 includes, for example, a pressure adjusting valve, such as a butterfly valve or the like. The gas exhaust flow path 22 is configured to enable the interior of the processing vessel 2 to be depressurized by the gas exhaust 24. A conveying port 25 is provided on a side surface of the processing vessel 2. The conveying port 25 is openable and closable by a gate valve 26. Loading and unloading of the substrate W between the processing vessel 2 and a conveying chamber (not shown) is performed via the conveying port 25.

A mounting table 3 for holding the substrate W substantially horizontally is provided in the processing vessel 2. The mounting table 3 has a substantially circular shape in a plan view, and is supported by a support member 31. A substantially circular recess 32 for mounting the substrate W having a diameter of, for example, 300 mm is formed on the surface of the mounting table 3. The recess 32 has an inner diameter that is slightly greater (by for example, approximately 1 mm to 4 mm) than the diameter of the substrate W. For example, the depth of the recess 32 is substantially equal to the thickness of the substrate W. The mounting table 3 is composed of a ceramic material, such as aluminum nitride (AlN) and the like. The mounting table 3 may be composed of a metal material, such as nickel (Ni) and the like. Instead of the recess 32, a guide ring for guiding the substrate W may be provided on the periphery of the surface of the mounting table 3.

A lower electrode 33, which is, for example, grounded, is embedded in the mounting table 3. A temperature adjusting mechanism 34 is embedded below the lower electrode 33. The temperature adjusting mechanism 34 adjusts the mounting table 3 or the substrate W mounted thereon to a set temperature based on a control signal from a controller 9. When the entirety of the mounting table 3 is composed of metal, the lower electrode 33 does not need to be embedded in the mounting table 3 because the entirety of the mounting table 3 functions as the lower electrode. The mounting table 3 is provided with a plurality of (for example, three) lifting pins 41 for rising and lowering while holding the substrate W mounted on the mounting table 3. The material of the lifting pins 41 may be, for example, ceramics, such as alumina (Al₂O₃) and the like, quartz, and the like. The lower ends of the lifting pins 41 is attached to a support plate 42. The support plate 42 is connected to a lifting mechanism 44 provided outside the processing vessel 2 via a lifting shaft 43.

The lifting mechanism 44 is provided, for example, under the gas exhaust chamber 21. A bellows 45 is provided between an opening 211 for the lifting shaft 43 formed in the lower surface of the gas exhaust chamber 21 and the lifting mechanism 44. The shape of the support plate 42 may a shape that can rise and lower without interfering with the support member 31 of the mounting table 3. The lifting pins 41 are configured to be able to rise and lower by the lifting mechanism 44 between above the surface of the mounting table 3 and under the surface of the mounting table 3. In other words, the lifting pins 41 are configured to be able to project from the upper surface of the mounting table 3.

An upper electrode (gas supply 5) is provided in a top wall 27 of the processing vessel 2 via an insulating member 28. The gas supply 5 constitutes an upper electrode, and faces the lower electrode 33. An RF power source 51 is connected to the gas supply 5 through a matcher 511. The frequency band of the RF power source 51 is, for example, from 450 kHz to 2.45 GHz. By supplying RF power from the RF power source 51 to the upper electrode (gas supply 5), an RF electric field is generated between the upper electrode (gas supply 5) and the lower electrode 33. The gas supply 5 includes a hollow gas diffusion chamber 52. A multitude of holes 53 for dispersively supplying a processing gas into the processing vessel 2 are, arranged in the lower surface of the gas diffusion chamber 52, for example, uniformly. A heating mechanism 54 is embedded in the gas supply 5 above, for example, the gas diffusion chamber 52. The heating mechanism 54 is heated to a set temperature by being supplied with power from a power source (not shown) based on a control signal from the controller 9.

The gas diffusion chamber 52 is provided with a gas supply path 6. The gas supply path 6 communicates with the gas diffusion chamber 52. A gas source 61 is connected to the upstream side of the gas supply path 6 through a gas line 62. The gas source 61 includes, for example, supply sources, mass flow controllers, and valves (none is shown) for various processing gases. The processing gases include gases used in a substrate processing method described later. The processing gases are introduced from the gas source 61 into the gas diffusion chamber 52 through the gas line 62.

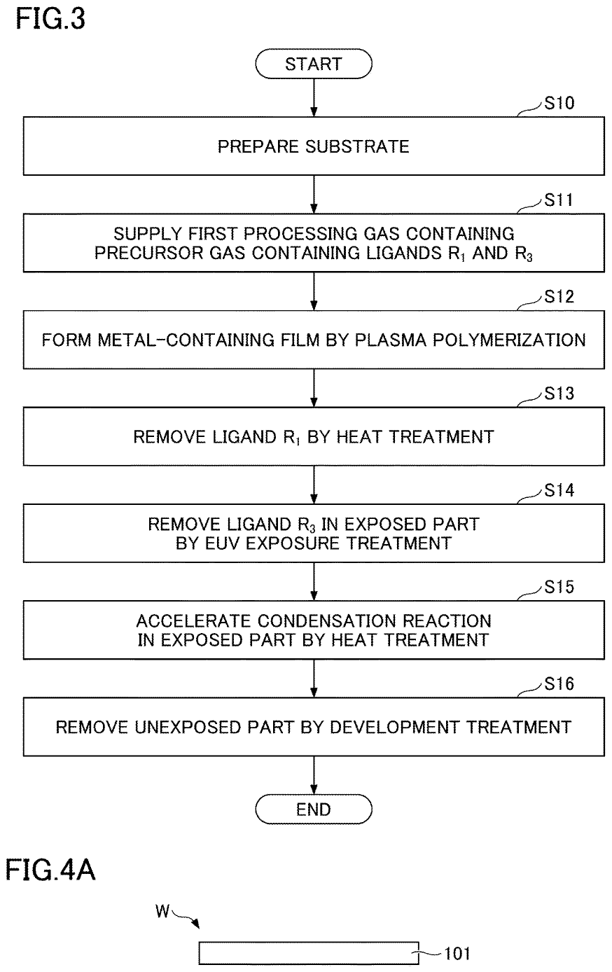

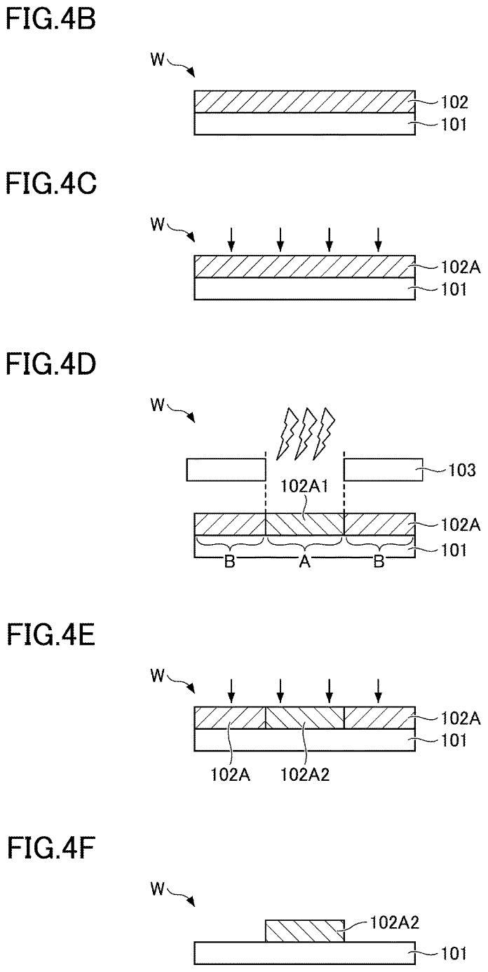

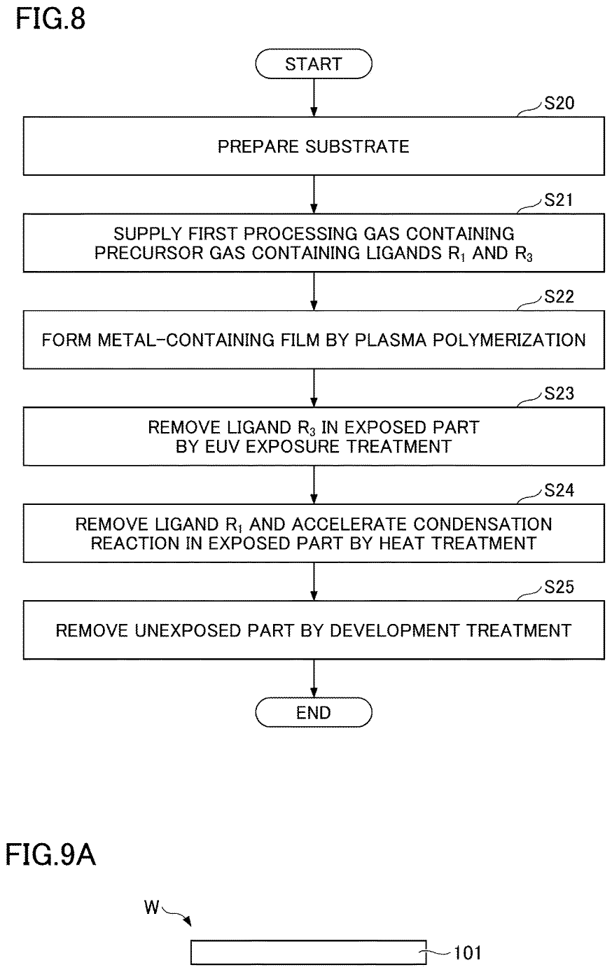

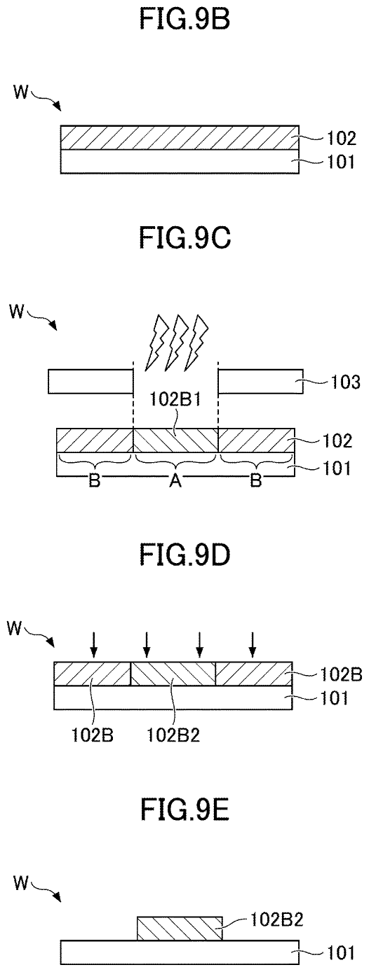

Examples of the processing gas include a first processing gas containing a metal-containing precursor gas. The first processing gas is a processing gas used for forming a metal-containing film 102 (see FIGS. 4B and 9B) in step S11 (see FIG. 3) and step S21 (see FIG. 8) described later.

The plasma processing apparatus 1 includes the controller 9. The controller 9 is, for example, a computer, and includes a Central Processing Unit (CPU), a Random Access Memory (RAM), a Read Only Memory (ROM), an auxiliary memory, and the like. The CPU operates based on a program stored in the ROM or the auxiliary memory, and controls the operation of the plasma processing apparatus 1. The controller 9 may be provided inside or outside the plasma processing apparatus 1. When the controller 9 is provided outside the plasma processing apparatus 1, the controller 9 can control the plasma processing apparatus 1 by a wired, wireless, or any other communication method.

As an example, a plasma processing apparatus for forming capacitively coupled plasma (CCP) has been described as the plasma processing apparatus 1, which, however, is not limited to this. The plasma processing apparatus 1 may be a plasma processing apparatus for forming a remote plasma by a high-frequency (RF, VHF) wave or a microwave (MW). The plasma processing apparatus for forming a remote plasma may be a plasma processing apparatus for forming a remote plasma in a processing vessel for housing the substrate W, or a plasma processing apparatus for supplying a formed remote plasma into the processing vessel for housing the substrate W.

### Method for Forming Resist Film According to Reference Example

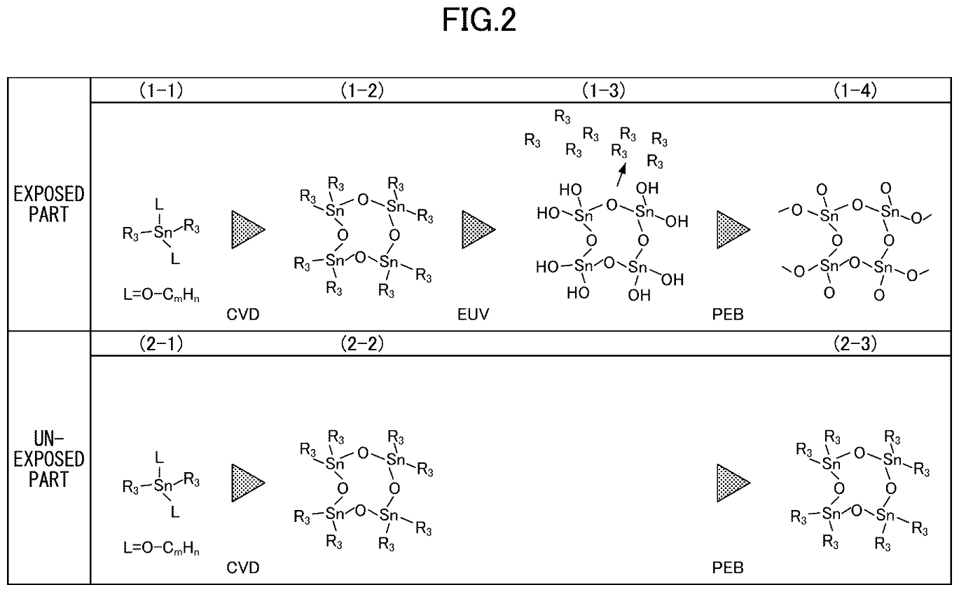

A method for forming a metal-containing resist film according to a reference example will be described with reference to FIG. 2. Hereinafter, a method for forming an Sn (tin) oxide resist film as an example of a metal-containing resist film will be described. FIG. 2 shows an example of film structures in the steps of forming a metal-containing resist film according to the reference example. FIG. 2 shows the film structure on the substrate W in each step, by dividing the substrate W into an exposed part and an unexposed part. In FIG. 2, the upper part shows film structures on an exposed part, and the lower part shows film structures on an unexposed part.

First, a metal-containing precursor gas is supplied into the processing vessel 2. As shown in (1-1) and (2-1) of FIG. 2, the supplied metal-containing precursor gas contains, as an example, a metal Sn, an alkoxy group L, and a ligand R₃. The alkoxy group L contains an O—CₘHₙ bond, where O is an oxygen atom, m is 0 or an integer of 1 or greater, and n is an integer of 1 or greater. The ligand R₃ is a substance derived from the precursor contained in the metal-containing precursor gas, and contains an M-CₐH_{b} bond. M is a metal (Sn), and a and b are integers of 1 or greater.

The plasma processing apparatus 1 forms a metal-containing film by using a CVD method. Here, a plasma is formed from the metal-containing precursor gas, and a metal-containing oligomer is deposited on the surface of the substrate W through a plasma polymerization reaction. Thus, as shown in (1-2) and (2-2) in FIG. 2, the metal-containing film containing the metal-containing oligomer is formed on the surface of the substrate W. The term “oligomer” refers to a polymer (multimer) in which a relatively small number (for example, fewer than twenty molecules) of monomers are bonded.

Next, the substrate W on which the metal-containing film is formed is subjected to an Extreme Ultraviolet (EUV) exposure treatment. In the exposure treatment, for example, in a vacuum, the metal-containing film is irradiated with EUV via a photomask having a predetermined pattern, to form an exposed part irradiated with EUV and an unexposed part not irradiated with EUV. As a result, in the exposed part, as shown in (1-3) in FIG. 2, the ligand R₃ in the metal-containing film is desorbed to convert the site to an OH group; the ligand R₃ is removed from the metal-containing film. On the other hand, the unexposed part is maintained in a soluble state.

Next, the exposed part and the unexposed part are heated by a heat treatment (Post-Exposure Bake: PEB). In the exposed part, condensation reaction between OH groups is promoted by the heat, and as shown in (1-4) in FIG. 2, the metal-containing film solidifies to form an insoluble Sn oxide resist film. On the other hand, in the unexposed part, the ligand R₃ inhibits heat energy-driven condensation reaction between OH groups. Therefore, as shown in (2-3) in FIG. 2, in the unexposed part, condensation reaction is inhibited by the ligand R₃ of the metal-containing film, and the metal-containing film does not solidify and remains soluble. In a development treatment, a treatment for a negative resist film is performed, to remove the unexposed part containing the soluble metal-containing film and keep in place the exposed part containing the insoluble metal-containing film by a wet process or a dry process. Thus, a metal-containing film (Sn oxide resist film) having a predetermined pattern is formed.

The sensitivity of the Sn oxide resist film is correlated with the binding energy between Sn and the ligand R₃ in the film. For example, since the oligomer shown in (1-2) of FIG. 2 is terminated by the ligand R₃, a high dose of exposure is required to sufficiently desorb the ligand R₃ by an exposure treatment (EUV) as shown in (1-3). This indicates that the binding energy between Sn and the ligand R₃ in the film is high, and that the sensitivity of the metal-containing film is low.

In other words, the lower the binding energy between Sn and the ligand R₃, the more possible it is to provide a metal-containing resist film having a higher sensitivity. Therefore, from the viewpoint of high sensitivity, a film structure in which the binding energy of the Sn—R bond is low is desirable. On the other hand, a film in which the binding energy of the Sn—R bond is low has an increased instability. Therefore, according to the resist film forming method according to the reference example, it is difficult to achieve both film stability and high sensitivity.

Hence, a film forming method according to a first embodiment and a second embodiment described below provides a substrate processing method for forming a metal-containing resist film (Sn oxide resist film) that can achieve both film stability and high sensitivity, by forming a metal-containing oligomer containing two types of ligands.

### FIRST EMBODIMENT

### Resist Film Forming Method

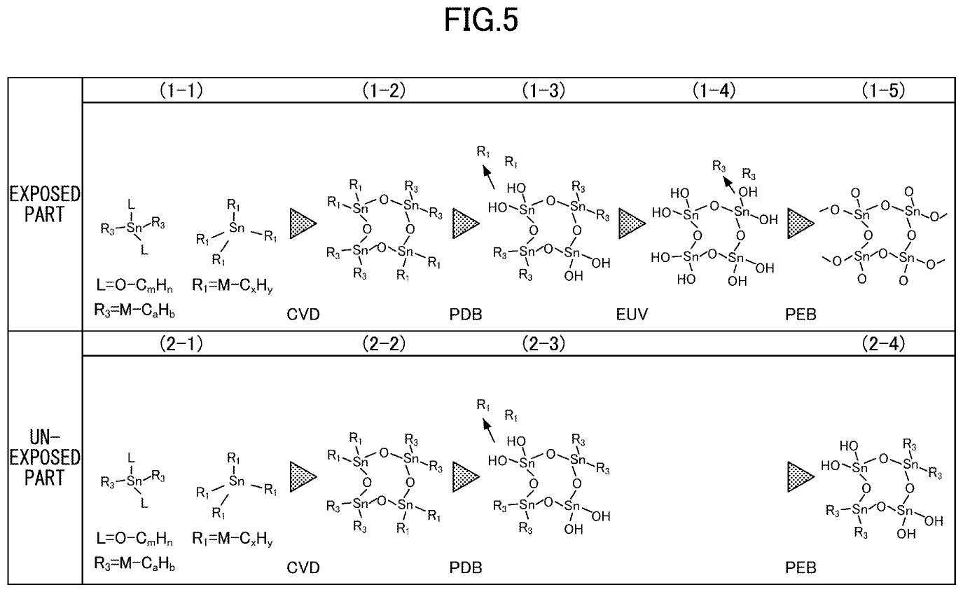

A substrate processing method for forming a metal-containing resist film according to the first embodiment will be described with reference to FIGS. 3 to 5. FIG. 3 is a flowchart showing an example of a substrate processing method for forming a metal-containing resist film according to the first embodiment. FIGS. 4A to 4F are views each showing an example of a film cross-section in each step for forming a film according to the first embodiment. FIG. 5 is a diagram showing an example of a film structure in each step for forming a film according to the first embodiment. FIG. 5 shows the film structure on the substrate W in each step, by dividing the substrate W into an exposed part and an unexposed part. In FIG. 5, the upper part shows the film structure of the exposed part, and the lower part shows the film structure of the unexposed part. In the following, a substrate processing method for forming an Sn oxide resist film as an example of a metal-containing resist film will be described.

### (Step S10)

In step S10, a substrate W is prepared in the processing vessel 2. As shown in FIG. 4A, the prepared substrate W includes a base film 101. The controller 9 controls a conveying device (not shown) to convey the substrate W containing the base film 101 into the processing vessel 2 of the plasma processing apparatus 1 and mount the substrate W in the recess 32 of the mounting table 3.

### (Step S11)

In step S11, a first processing gas containing a metal-containing precursor gas that contains oxygen, a ligand R₃, and a ligand R₁, the ligand R₃ and the ligand R₁ having different thermal reactivities, is supplied into the processing vessel 2. The metal-containing precursor gas may be an organometallic precursor gas containing oxygen. The organometallic precursor gas containing oxygen may contain an alkoxy group L.

The alkoxy group L contains an O—CₘHₙ bond. O is an oxygen atom, m is 0 or an integer of 1 or greater, and n is an integer of 1 or greater.

The ligand R₃ is a substance derived from the precursor contained in the metal-containing precursor gas, and contains an M-CₐH_{b} bond. M is a metal, and a and b are integers of 1 or greater.

The ligand R₁ is a substance derived from the precursor contained in the metal-containing precursor gas, and contains an M-CₓH_{y} bond. M is a metal, x is smaller than a and x is 0 or an integer of 1 or greater, and y is an integer of 1 or greater.

M may be one selected from Sn, Sb, In, Al, Ti, Mn, Ta, Hf, W, Te, and Bi.

The metal-containing precursor gas contains a plurality of types of precursors, namely, a first precursor containing the M-CₐH_{b} bond, and a second precursor containing the M-CₓH_{y} bond. However, this is non-limiting, and the metal-containing precursor gas may contain one type of a precursor containing the M-CₐH_{b} bond and the M-CₓH_{y} bond.

As shown in (1-1) and (2-1) of FIG. 5, the metal-containing precursor gas contains the first precursor containing the M-CₐH_{b} bond and the second precursor containing the M-CₓH_{y} bond. In the first precursor, two alkoxy groups L and two ligands R₃ are bonded to Sn. In the second precursor, four ligands R₁ are bonded to Sn. However, in the second precursor, at least one ligand R₁ needs only to be bonded to Sn, and the remaining bonds to Sn do not need to be ligands R₁.

The ligand R₁ has a first thermal reactivity, and the ligand R₃ has a second thermal reactivity lower than the first thermal reactivity. That is, the ligand R₁ reacts at a heating temperature lower than that of the ligand R₃. The ligand R₃ has a first photoreactivity, and the ligand R₁ has a second photoreactivity lower than the first photoreactivity. That is, the ligand R₃ reacts at a dose of exposure lower than that for the ligand R₁.

The ligand R₁ is an example of a second ligand having a first thermal reactivity. The ligand R₃ is an example of a first ligand having a second thermal reactivity lower than the first thermal reactivity.

Here, the controller 9 controls the gas source 61 to supply the first processing gas containing the metal-containing precursor gas into the processing vessel 2 from the gas supply 5 through the multitude of holes 53. The controller 9 controls the RF power source 51 to supply RF power to the upper electrode (gas supply 5). Thus, a plasma is formed from the first processing gas in the processing vessel 2, and the substrate W is exposed to the formed plasma.

### (Step S12)

In step S12, a metal-containing film 102 is formed on the surface of the substrate W through polymerization reaction of the formed plasma (see FIG. 4B). The metal-containing film 102 contains the ligand R₁ and the ligand R₃. As shown in (1-2) and (2-2) of FIG. 5, the metal-containing film 102 is a deposited product of a metal-containing oligomer containing the metal (M), oxygen (O), carbon (C), and hydrogen (H). Here, the metal (M) is one selected from Sn, Sb, In, Al, Ti, Mn, Ta, Hf, W, Te, and Bi. Thus, the metal-containing film 102 containing two types of ligands having different thermal reactivities is formed.

Specifically, the metal-containing precursor gas may be, for example, two gases selected from Sn(OC₄H₉)₄, Sn(OC₄H₉)₂(CH₃)₂, Sn(OC₄H₉)₂(C₂H₅)₂, Sn(OC₄H₉)₂(C₃H₈)₂, Sn(OC₄H₉)₂(C₄H₉)₂, Sn(OC₄H₉)₃(CH₃)₁, Sn(OC₄H₉)₃, (C₂H₅)₁, Sn(OC₄H₉)₃(C₃H₈)₁, Sn(OC₄H₉)₃(C₄H₉)₁, Sn(CH₃)₄, SnH(CH₃)₃, SnH₂(CH₃)₂, Sn(C₂H₅)₄, Sn(C₃H₈)₄Sn(C₄H₉)₄, Al(CH₃)₃, Co(C₅H₅)₂, SnR₄, SnHR₃ (where R is —CH₃, —C₂H₃, —C₃H₅, —C₄H₇, or —C₆H₆). The two precursor gases selected have a relationship of one containing Sn—CₐH_{b} bonds and the other containing Sn—CₓH_{y} bonds.

The first processing gas may contain either or both of an additive gas and an inert gas. The additive gas is at least one gas selected from H₂, CH₄, C₂H₂, C₂H₄, and C₃H₆. By adding the additive gas, it is possible to form M-CₐH_{b} and M-CₓH_{y} bonds during the film formation. From the viewpoint of stability and cost, it is not always possible to use a desirable M-CₐH_{b} bond- and M-CₓH_{y} bond-containing material as the metal-containing precursor gas. Therefore, by addition of the additive gas and control of the concentration, it is possible to impart desirable M-CₐH_{b} bonds and M-CₓH_{y} bonds and a desirable concentration. This makes it possible for the film to contain desirable bonds without being constrained by the metal-containing precursor gas. In addition, this makes it possible to improve the degree of freedom in selecting thermal reactivity and photoreactivity. The inert gas as a material is at least one gas selected from He, Ar, Ne, Xr, or N₂.

An example of a recipe in the step of forming the metal-containing film 102 is shown below.
Plasma type: CCP, 13.56 MHz, 10 W to 500 W
Substrate temperature: −10 °C or higher and 310 °C or lower
Pressure in the processing vessel: 100 mTorr (13.3 Pa) to 20 Torr (26.7 Pa)

Next, the controller 9 controls the conveying device (not shown) to unload the substrate W from the processing vessel 2 of the plasma processing apparatus 1. The processing from step S10 to step S12 is performed in the processing vessel 2 in a reduced pressure atmosphere.

### (Step S13)

In step S13, the metal-containing film 102 is subjected to a heat treatment (Post Deposition Bake: PDB) (see FIG. 4C). Specifically, the metal-containing film 102 is reacted with oxygen or water at a predetermined temperature to desorb the ligand R₁ and convert the site to an OH group, thereby forming an Sn—OH bond and removing the ligand R₁. As a result, the metal-containing film 102A on the surface of the substrate W comes to have a film structure in which the ligand R₁ is removed from the metal-containing film 102 and the ligand R₃ remains, as shown in (1-3) and (2-3) in FIG. 5.

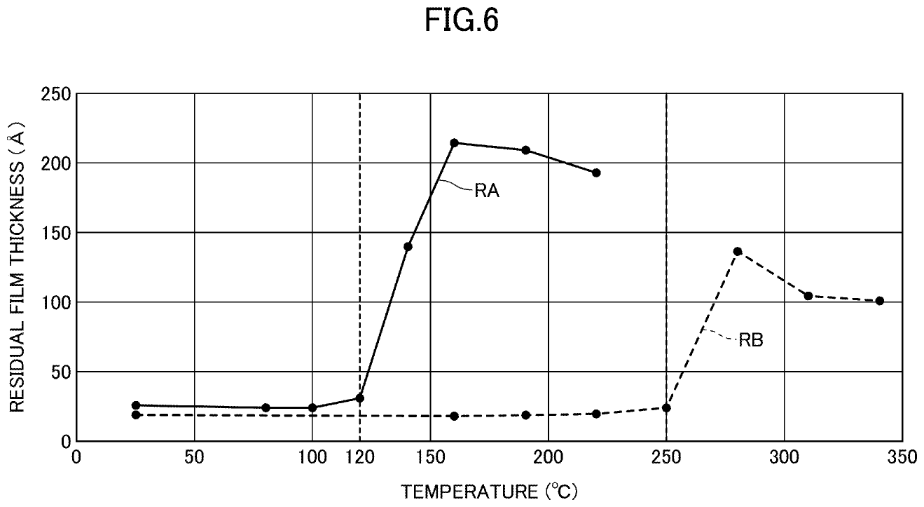

FIG. 6 is a diagram showing an example of the result of an experiment regarding dependency of the solubility of the metal-containing film 102 on the temperature. In FIG. 6, the horizontal axis indicates the temperature of the substrate W, and the vertical axis indicates the thickness of the residual film of the metal-containing film 102. The residual film thickness increases as the metal-containing film 102 more solidifies. The metal-containing film 102 more solidifies as the process in which the ligand R₁ is desorbed to convert the site to an OH group and the ligand R₁ is removed more proceeds. The line RA indicates the temperature dependency of the solubility of the metal-containing film in which Sn oxide is terminated by the ligand R₁. The line RB indicates the temperature dependency of the solubility of the metal-containing film in which Sn oxide is terminated by the ligand R₃. As a result of the experiment, the metal-containing film in which Sn oxide is terminated by the ligand R₁ indicated by the line RA changed to an insoluble film when the substrate W was controlled to 120 °C or higher. On the other hand, the metal-containing film in which Sn oxide is terminated by the ligand R₃ indicated by the line RB was maintained as a soluble film when the substrate W was controlled to 120 °C or higher and lower than 250 °C, and changed to an insoluble film when the mounting table 3 was controlled to 250 °C or higher.

Therefore, in step S13, by controlling the substrate W at a temperature of 120 °C or higher and lower than 250 °C, it is possible to form the metal-containing film 102A composed of the metal-containing oligomer in which the ligand R₁ is desorbed and removed whereas the ligand R₃ remains. Thus, the ligand R₃ in the metal-containing film 102A inhibits solidification of the metal-containing film 102A. In this way, as shown in (1-3) and (2-3) in FIG. 5, through the heat treatment (PDB), a metal-containing oligomer in which the ligand R₃ and the OH group coexist can be formed. Thus, the metal-containing film 102A (metal-containing resist film) having high photoreactivity (sensitivity) in the exposure treatment in the next step and having excellent film stability as well can be formed.

### (Step S14)

In step S14, the substrate W having the metal-containing film 102A formed on the base film 101 is subjected to exposure treatment (EUV). Here, as shown in FIG. 4D, in a vacuum, the metal-containing film 102A is irradiated with EUV via a photomask 103 having a predetermined pattern to form an exposed part A irradiated with EUV and an unexposed part B not irradiated with EUV.

As a result, in the exposed part A, the bond between the ligand R₃ having high photoreactivity and Sn is disconnected, to induce reaction with oxygen or water to form an Sn—OH bond and desorb the ligand R₃, thereby converting the site to an OH group. Further, a condensation reaction between the OH groups proceeds. As a result, as shown in (1-4) in FIG. 5, the ligand R₃ is removed from the film of the exposed part A, and a metal-containing film 102A1 composed of a metal-containing oligomer containing the Sn—OH bond is formed. Since the unexposed part B is not irradiated with EUV, it remains as the film structure of the metal-containing film 102A.

### (Step S15)

In step S15, the substrate W subjected to the exposure treatment (EUV) is subjected to a heat treatment (Post Exposure Bake: PEB). Here, condensation reaction of the metal-containing oligomer in the exposed part A is accelerated by the heat treatment.

That is, by acceleration of the condensation reaction between the Sn—OH bonds in the film in the exposed part A, the film solidifies and forms an insoluble metal-containing resist film 102A2 as shown in FIG. 4E. (1-5) in FIG. 5 shows that the condensation reaction of the metal-containing oligomer in the exposed part A is accelerated by the heat treatment (PEB), to form the insoluble metal-containing resist film 102A2 (Sn oxide resist film) containing Sn—O bonds.

On the other hand, in the unexposed part B, condensation reaction of the metal-containing oligomer is inhibited by the ligand R₃ in the metal-containing film 102A, and solubility is maintained, which provides development characteristics. Thus, the metal-containing film 102A in the unexposed part B becomes a film that can be removed by the development treatment in the next step.

### (Step S16)

In step S16, the substrate W is subjected to the development treatment. Here, the unexposed part B is selectively removed through the developing treatment (see FIG. 4F). The developing treatment may employ at least one of a wet process or a dry process.

When the developing treatment employs a wet process, the substrate W is exposed to an organic solvent to selectively remove the unexposed part B. The organic solvent may be, for example, an alcohol.

When the developing treatment employs a dry process, the substrate W is exposed to a halogen-containing gas to increase the etching rate at the unexposed part B and selectively remove the unexposed part B. The halogen-containing gas may be at least one of HBr, HCl, or BCl₃.

As described above, according to the film forming method according to the first embodiment, the metal-containing resist film 102A2 can be formed on the base film 101. The metal-containing film 102 formed in the plasma processing apparatus 1 can be a negative resist film from which the unexposed part B can be selectively removed.

Further, a metal-containing film containing two types of ligands R₁ and R₃ having different thermal reactivities is formed, and through the heat treatment (PDB), the ligand R₁ is desorbed to convert the site to an OH group. Further, through the exposure treatment (EUV), the ligand R₃ is desorbed to convert the site to an OH group. Then, by acceleration of the condensation reaction of the OH groups through the heat treatment (PEB), a metal-containing resist film having high sensitivity and excellent stability can be formed.

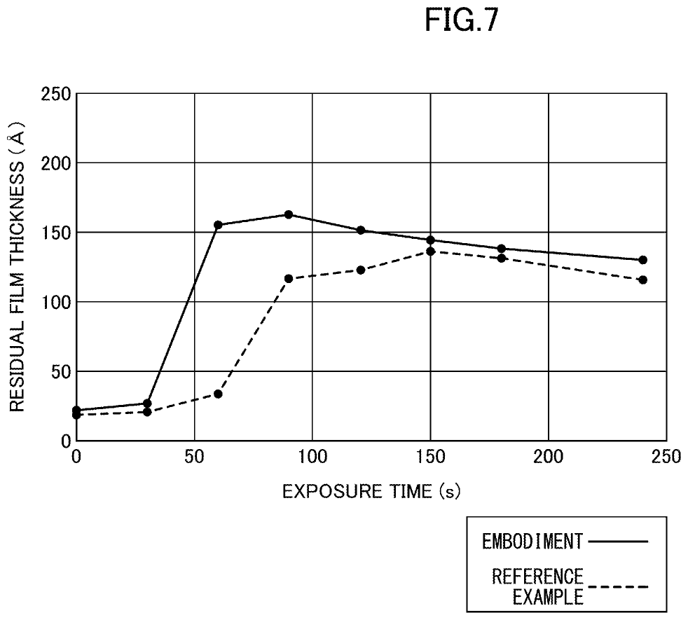

FIG. 7 is a diagram showing an example of the result of an experiment regarding the sensitivity of the metal-containing film. In FIG. 7, the horizontal axis indicates the exposure time, and the vertical axis indicates the residual film thickness (thickness of the residual film). The reference example indicated by the broken line in FIG. 7 shows the relationship between the exposure time and the residual film thickness when a metal-containing film containing the one type of the ligand R₃ shown in (1-2) of FIG. 2 is subjected to exposure treatment (EUV).

The embodiment indicated by the solid line in FIG. 7 shows the relationship between the exposure time and the residual film thickness when a metal-containing film containing the two types of the ligands R₁ and R₃ shown in (1-2) of FIG. 5 is subjected to exposure treatment (EUV) after removal of the ligand R₁ by heat treatment (PDB).

The dose of exposure increases as the exposure time increases. In the experiment of FIG. 7, the residual film thickness of the embodiment experienced a sharp increase at a lower dose of exposure than did the residual film of the reference example. The timing at which the residual film thickness increases sharply indicates switching of the metal-containing a soluble state to an insoluble state. That is, an earlier timing at which the residual film thickness increases sharply indicates that the ligand R₃ in the metal-containing film was removed at a lower dose of exposure.

In the reference example, since it was necessary to disconnect the bonds of all ligands R₃ in the film, the metal-containing film did not change to an insoluble film unless the dose of exposure was increased. On the other hand, in the embodiment, since the timing at which the residual film thickness increases sharply was earlier than in the reference example, it was possible to disconnect the bonds of the ligands R₃ in the film by irradiation with light with a lower dose of exposure than in the reference example. That is, in the embodiment, a metal-containing resist film with higher sensitivity compared with the reference example was obtained. In the embodiment, since the ligand R₁ was desorbed from the metal-containing film in advance through the heat treatment (PDB), an insoluble metal-containing resist film was obtained at a lower dose of exposure than in the reference example.

### SECOND EMBODIMENT

### Method for Forming Resist Film

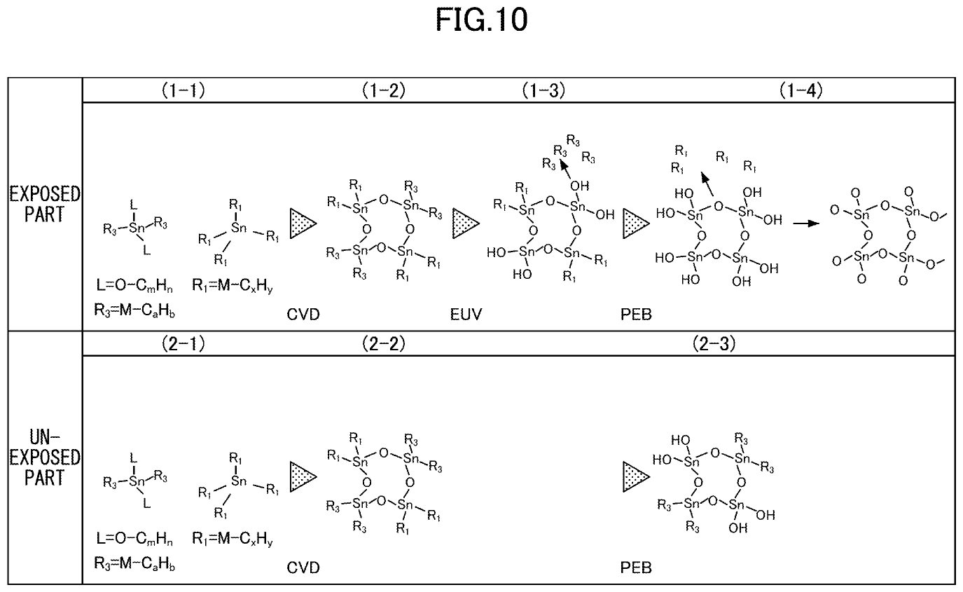

Next, a substrate processing method for forming a metal-containing resist film according to the second embodiment will be described with reference to FIGS. 8 to 10. FIG. 8 is a flowchart showing an example of the substrate processing method for forming a metal-containing resist film according to the second embodiment. FIGS. 9A to 9E are views each showing an example of a film cross section in each step for forming a film according to the second embodiment. FIG. 10 is a view showing an example of a film structure in each step for forming a film according to the second embodiment. FIG. 10 shows the film structure on the substrate W in each step, by dividing the substrate W into an exposed part and an unexposed part. In FIG. 10, the upper part shows the film structure of the exposed part, and the lower part shows the film structure of the unexposed part. In the following, a substrate processing method for forming an Sn oxide resist film as an example of a metal-containing resist film will be described.

### (Step S20)

In step S20, a substrate W is prepared in the processing vessel 2. As shown in FIG. 9A, the prepared substrate W includes a base film 101.

### (Step S21)

In step S21, a first processing gas containing a metal-containing precursor gas that contains oxygen and ligands R₃ and R₁ having different thermal reactivities is supplied into the processing vessel 2. The metal-containing precursor gas may be an organometallic precursor gas containing oxygen. Further, the organometallic precursor gas containing oxygen may contain an alkoxy group L.

As shown in (1-1) and (2-1) in FIG. 10, the metal-containing precursor gas contains a first precursor containing an M-CₐH_{b} bond and a second precursor containing an M-CₓH_{y} bond, wherein two alkoxy groups L and two ligands R₃ are bonded to Sn in the first precursor, and four ligands R₁ are bonded to Sn in the second precursor. However, at least one ligand R₁ needs only to be bonded to Sn in the second precursor, and the remaining bonds to Sn do not need to be the ligands R₁.

Since the configurations of the metal-containing precursor gas and the first processing gas containing the metal-containing precursor gas are the same as those of the first processing gas used in the first embodiment, the description thereof is omitted here.

### (Step S22)

In step S22, a metal-containing film 102 is formed on the surface of the substrate W through a polymerization reaction of a formed plasma (see FIG. 9B). The metal-containing film 102 contains the ligand R₁ and the ligand R₃. As shown in (1-2) and (2-2) in FIG. 10, the metal-containing film 102 is a deposited product of a metal-containing oligomer containing the metal (M), oxygen (O), carbon (C), and hydrogen (H). Here, the metal (M) is one selected from Sn, Sb, In, Al, Ti, Mn, Ta, Hf, W, Te, and Bi. Thus, the metal-containing film 102 containing two types of ligands having different thermal reactivities is formed.

An example of a recipe in the step of forming the metal-containing film 102 is shown below.
Plasma type: CCP, 13.56 MHz, 10 W to 500 W
Substrate temperature: −10 °C or higher and 310 °C or lower
Pressure in the processing vessel: 100 mTorr (13.3 Pa) to 20 Torr (26.7 Pa)

The process from step S20 to step S22 is performed in the processing vessel 2 in a reduced pressure atmosphere.

### (Step S23)

In step S23, the substrate W having the metal-containing film 102 formed on the base film 101 is subjected to exposure treatment (EUV). Here, as shown in FIG. 9C, in a vacuum, the metal-containing film 102 is irradiated with EUV via a photomask 103 having a predetermined pattern to form an exposed part A irradiated with EUV and an unexposed part B not irradiated with EUV.

As a result, in the exposed part A, the bond between the ligand R₃ having high photoreactivity and Sn is disconnected to induce reaction with oxygen or water to form an Sn—OH bond, to thereby desorb the ligand R₃ and convert the site to an OH group. Further, a condensation reaction between OH groups proceeds. As a result, as shown in (1-3) in FIG. 10, the ligand R₃ is removed from the film of the exposed part A, to form a metal-containing film 102B1 composed of a metal-containing oligomer containing the ligand R₁ and an Sn—OH bond (see FIG. 9C). Since the unexposed part B is not irradiated with EUV, it remains as the film structure of the metal-containing film 102.

In the exposure treatment, there may be a case in which part of the ligand R₁ is desorbed to convert the site to an OH group, to thereby the ligand R₁. However, at least part of the ligand R₁ remains in the metal-containing film 102B1.

### (Step S24)

In step S24, the substrate W subjected to the exposure treatment (EUV) is subjected to a heat treatment (Post Exposure Bake: PEB). Here, the bond between the ligand R₁ having high thermal reactivity and Sn is disconnected, to induce reaction with oxygen or water to form an Sn—OH bond and desorb the ligand R₁ and convert the site to an OH group. In addition, condensation reaction of the metal-containing oligomer in the exposed part A is accelerated along with the desorption of the ligand R₁.

That is, the film is solidified by the acceleration of the condensation reaction between the Sn—OH bonds in the film of the exposed part A, to form an insoluble metal-containing resist film 102B2 as shown in FIG. 9D. (1-4) in FIG. 10 shows that after the ligand R₁ is desorbed and removed through the heat treatment (PEB), the condensation reaction of the metal-containing oligomer in the exposed part A proceeds, to form an insoluble Sn oxide metal-containing resist film 102B2 containing an Sn—O bond.

On the other hand, in the unexposed part B, the ligand R₁ having high thermal reactivity is desorbed and removed through the heat treatment (PEB), whereas the ligand R₃ having low thermal reactivity remains in the film as shown in (2-3) in FIG. 10. Thus, a metal-containing film 102B containing the ligand R₃ is formed in the unexposed part B (see FIG. 9D). The ligand R₃ in the metal-containing film 102B inhibits condensation reaction, to maintain the solubility, which provides development characteristics. Thus, the metal-containing film 102B in the unexposed part B is a film that can be removed by the development treatment in the next step.

### (Step S25)

In step S25, the substrate W is subjected to the development treatment. Here, the unexposed part B (see FIG. 9E) is selectively removed through the development treatment. The development treatment can employ at least one of a wet process or a dry process.

When the development treatment employs a wet process, the substrate W is exposed to an organic solvent to selectively remove the unexposed part B. The organic solvent may be, for example, an alcohol.

When the developing treatment employs a dry process, the substrate W is exposed to a halogen-containing gas to increase the etching rate at the unexposed part B and selectively remove the unexposed part B. The halogen-containing gas may be at least one of HBr or HCl.

As described above, according to the film forming method according to the second embodiment, the metal-containing resist film 102B2 can be formed on the base film 101. The metal-containing film 102 formed in the plasma processing apparatus 1 can be a negative resist film from which the unexposed part B can be selectively removed.

A metal-containing film containing two types of ligands R₁ and R₃ having different thermal reactivities is formed, and the ligand R₃ is desorbed through the exposure treatment (EUV) to convert the site to an OH group. Then, the ligand R₁ is desorbed through the heat treatment (PEB) to convert the site to an OH group, thereby accelerating the condensation reaction between OH groups. Thus, it is possible to form a metal-containing resist film having high sensitivity and excellent stability.

In the film forming method according to the first embodiment, the heat treatment (PDB) is performed before the exposure treatment (EUV). Therefore, in the first embodiment, the ligand R₁ in the metal-containing film is desorbed and removed first by the heat treatment (PDB), and the ligand R₃ is then desorbed and removed next by the exposure treatment.

On the other hand, in the film forming method according to the second embodiment, no heat treatment (PDB) before the exposure treatment is performed. Therefore, in the second embodiment, the ligand R₃ in the metal-containing film is desorbed and removed first by the exposure treatment (EUV), and the ligand R₁ is desorbed and removed next by the heat treatment (PEB).

As described above, in the second embodiment, the ligand R₃ is desorbed and removed from the metal-containing film before the ligand R₁. Since the ligand R₃ contains a greater number of carbons (C) than that in the ligand R₁, desorbing and removing the ligand R₃ from the metal-containing film first results in a metal-containing film having a lower carbon content, and a metal-containing film having better exposure characteristics (sensitivity) can be formed.

### Others

In the heat treatment (PDB), the exposure treatment (EUV), and the heat treatment (PEB) in which the metal-containing film 102 is reacted with oxygen or water to form Sn—OH bonds, and desorb and remove the ligand R₁ or the ligand R₃, an oxidizing agent, such as H₂O, O₂, and the like, may be used, or does not need to be used. For example, by performing the heat treatment (PDB), the exposure treatment (EUV), and the heat treatment (PEB) in an open-air atmosphere, the ligand R₁ or the ligand R₃ may be desorbed and the site may be converted to an OH group using a water or oxygen component in the atmosphere. Alternatively, the ligand R₁ or the ligand R₃ may be desorbed and the site may be converted to an OH group using a hydrogen or oxygen component contained in the metal-containing film 102.

By increasing the number of C atoms contained in the ligand R₁ from 4 to 5, 6, . . . , it is possible to increase the temperature until which a metal-containing film containing the ligand R₁ maintains solubility to approximately 310 °C.

By changing the number of C atoms contained in the ligand R₁ in this way, it is possible to control the substrate W at a temperature of 120 °C or higher and lower than 310 °C in the heat treatment (PDB). Thus, a metal-containing film having desired film stability and high sensitivity can be formed.

As described above, according to the substrate processing method and the plasma processing apparatus of the present embodiment, it is possible to form a metal-containing film that achieves both film stability and high sensitivity.

The substrate processing method and the plasma processing apparatus according to the embodiments disclosed herein should be considered exemplary and not restrictive in all respects. The embodiments can be modified and improved in various forms without departing from the scope and the spirit of the appended claims. The particulars described in the plurality of embodiments can be configured in other forms to the extent that no contradiction occurs, and can be combined to the extent that no contradiction occurs.

According to one aspect, it is possible to form a metal-containing film that can achieve both stability and high sensitivity as a resist film.

What is claimed is:

1. A substrate processing method, comprising:
(A) preparing a substrate;
(B) forming, on a surface of the substrate, a metal-containing film that contains oxygen, a first ligand, and a second ligand, the first ligand and the second ligand having different thermal reactivities;
(C) heat-treating the metal-containing film; and
(D) irradiating the metal-containing film with extreme ultraviolet rays under a predetermined pattern, to form an exposed part irradiated with the extreme ultraviolet rays and an unexposed part not irradiated with the extreme ultraviolet rays in the metal-containing film.

2. The substrate processing method according to claim 1,
wherein the second ligand has a first thermal reactivity, and
the first ligand has a second thermal reactivity lower than the first thermal reactivity.

3. The substrate processing method according to claim 2,
wherein, after the second ligand is removed from the metal-containing film in the (C), the first ligand is removed from the exposed part in the (D).

4. The substrate processing method according to claim 3,
wherein, after the second ligand contained in the metal-containing film is converted to an OH group in the (C), the first ligand contained in the exposed part is converted to an OH group in the (D), and
the substrate processing method further comprises:
(E) after the (D), heat-treating the metal-containing film to cause the OH groups to undergo a condensation reaction.

5. The substrate processing method according to claim 2,
wherein, after the first ligand is removed from the exposed part in the (D), the second ligand is removed from the metal-containing film in the (C).

6. The substrate processing method according to claim 5,
wherein, after the first ligand contained in the exposed part is converted to an OH group in the (D), the second ligand contained in the metal-containing film is converted to an OH group, and the OH groups are caused to undergo a condensation reaction in the (C).

7. The substrate processing method according to claim 1,
wherein, in the (C), a mounting table on which the substrate is mounted is controlled at a temperature of 120 °C or higher and lower than 310 °C.

8. The substrate processing method according to claim 7,
wherein, in the (C), the mounting table on which the substrate is mounted is controlled at a temperature of 120 °C or higher and lower than 250 °C.

9. The substrate processing method according to claim 1,
wherein, in the (B), a first processing gas containing a metal-containing precursor gas that contains the oxygen, the first ligand, and the second ligand, the first ligand and the second ligand having the different thermal reactivities, is supplied into a processing vessel, and a plasma of the first processing gas is formed, to form the metal-containing film containing the oxygen, the first ligand, and the second ligand on the surface of the substrate through a plasma polymerization reaction.

10. The substrate processing method according to claim 9,
wherein the metal-containing precursor gas contains an M-CₐH_{b} bond and an M-CₓH_{y} bond, where M is a metal, a and b are integers of 1 or greater, x is 0 or an integer of 1 or greater, and y is an integer of 1 or greater.

11. The substrate processing method according to claim 10,
wherein the metal-containing precursor gas contains an O—CₘHₙ bond, where O is an oxygen atom, m is 0 or an integer of 1 or greater, and n is an integer of 1 or greater.

12. The substrate processing method according to claim 10,
wherein the metal-containing precursor gas contains a plurality of precursors including: a first precursor containing the M-CₐH_{b} bond; and a second precursor containing the M-CₓH_{y} bond.

13. The substrate processing method according to claim 10,
wherein the metal-containing precursor gas contains one type of a precursor containing the M-CₐH_{b} bond and the M-CₓH_{y} bond.

14. The substrate processing method according to claim 10,
wherein the M is one selected from the group consisting of Sn, Sb, In, Al, Ti, Mn, Ta, Hf, W, Te, and Bi.

15. The substrate processing method according to claim 1,
wherein an interior of a processing vessel in which the (D) is performed is in a vacuum.

16. The substrate processing method according to claim 4,
wherein, in the (E), the substrate is controlled at a temperature of −10 °C or higher and 310 °C or lower.

17. The substrate processing method according to claim 9,
wherein the first processing gas contains at least one of an additive gas or an inert gas,
the additive gas is at least one gas selected from H₂, CH₄, C₂H₂, C₂H₄, and C₃H₆, and
the inert gas is at least one gas selected from He, Ar, Ne, Xr, and N₂.

18. The substrate processing method according to claim 1, further comprising:
(F) selectively removing the unexposed part from the metal-containing film.

19. A plasma processing apparatus, comprising:
a processing vessel;
a mounting table configured for a substrate to be mounted;
a gas supply configured to supply a gas into the processing vessel;
a plasma source configured to supply electric power via an upper electrode provided in a top wall of the processing vessel; and
a controller including a processor and a memory,
wherein the controller is configured to control:
(A) preparing the substrate on the mounting table in the processing vessel;
(B) supplying a first processing gas containing a metal-containing precursor gas from the gas supply into the processing vessel, the metal-containing precursor gas containing oxygen, a first ligand, and a second ligand, the first ligand and the second ligand having different thermal reactivities, and supplying electric power from the plasma source via the upper electrode, to form a plasma of the first processing gas and to cause the first processing gas to undergo plasma polymerization, to form a metal-containing film containing the oxygen, the first ligand, and the second ligand on a surface of the substrate.

20. A substrate processing method, comprising:
forming on the surface of the substrate, by the plasma processing apparatus of claim 19, the metal-containing film that contains the oxygen, the first ligand, and the second ligand.
